(19) United States
(12) Patent Application Publication
(10) Pub. No.: US 2026/0363012 A1
(43) Pub. Date: Nov. 12, 2026

(54) SYSTEMS AND METHODS FOR DEGASSING A SUBSTRATE

(71) Applicant: ASM IP Holding B.V., Almere (NL)

(72) Inventors: Masaei Suwada, Nagaoka-shi (JP); Taira Okabe, Kawasaki-shi (JP); Samer Banna, Phoenix, AZ (US)

(21) Appl. No.: 19/654,877

(22) Filed: Apr. 22, 2026

Related U.S. Application Data
(60) Provisional application No. 63/795,054, filed on Apr. 25, 2025.

(51) Int. Cl. H10P 72/00; C23C 16/02; F26B 21/40; H10P 72/76

(52) U.S. Cl. CPC H10P 72/0402; C23C 16/0209; F26B 21/40; H10P 72/0436; H10P 72/7604

(57) ABSTRACT

Methods and systems for degassing a substrate are provided. In an example, the system includes a load lock chamber body, defining a load lock chamber and including a first face to be coupled to a transfer module and a second face that can be coupled to a vacuum chamber. The system further includes a degas module disposed within the load lock chamber that can degas the substrate, which includes a substrate holder that can hold the substrate, a rotation mechanism that can rotate the substrate holder, a ramp heater that can apply heat to the substrate, and a gas nozzle that can blow gas toward the substrate.

### CROSS-REFERENCE TO RELATED APPLICATIONS

This application claims priority to U.S. Provisional Patent Application Ser. No. 63/795,054 filed Apr. 25, 2025 titled SYSTEMS AND METHODS FOR DEGASSING A SUBSTRATE, the disclosure of which is hereby incorporated by reference in its entirety.

### FIELD

The disclosure generally relates to the fields of microfabrication and nanofabrication. In particular, the present disclosure relates to the field of semiconductor fabrication processing, for example, the fabrication of integrated circuits.

### BACKGROUND OF THE DISCLOSURE

There is continuing interest in improving the efficiency and quality of thin film deposition in semiconductor manufacturing. It is generally accepted that gas and/or moisture adsorption onto incoming wafers can significantly affect the film deposition quality of process tools and throughput of substrates. Moisture on wafer surfaces can, for example, prevent good adhesion during film deposition and increase the risk of oxidation and poor resistivity performance on metal films. Monolayers of moisture can easily accumulate on wafer surfaces during transportation from a Front Opening Unified Pod (FOUP) to a load lock vacuum chamber if the wafer passes through an air-flown environment inside an Equipment Front End Module (EFEM) space.

However, conventional solutions for wafer degassing are time-consuming and occupy valuable space that could otherwise be used for wafer processing. Despite the importance of efficient moisture desorption and gas removal, limited innovation has been focused on addressing these challenges. In light of the above, it may be desirable to develop novel solutions related to enhancing moisture desorption (e.g., degassing) efficiency in semiconductor manufacturing tools.

Any discussion, including discussion of problems and solutions, set forth in this section has been included in this disclosure solely for the purpose of providing a context for the present disclosure. Such discussion should not be taken as an admission that any or all of the information was known at the time the invention was made or otherwise constitutes prior art.

### SUMMARY

This summary is provided to introduce a selection of concepts in a simplified form. These concepts are described in further detail in the detailed description of example aspects of the disclosure below. This summary is not intended to identify key features or essential features of the claimed subject matter, nor is it intended to be used to limit the scope of the claimed subject matter.

Example systems as disclosed herein are configured for degassing a substrate. In an example, the system comprises a load lock chamber body, defining a load lock chamber and comprising a first face to be coupled to a transfer module and a second face configured to be coupled to a vacuum chamber. The system further comprises a degas module disposed within the load lock chamber and configured to degas the substrate, which comprises a substrate holder configured to hold the substrate, a rotation mechanism configured to rotate the substrate holder, a ramp heater configured to apply heat to the substrate, and a gas nozzle configured to blow gas toward the substrate.

In an example, the rotation mechanism rotates the substrate holder about a central access of the substrate. In an example, the ramp heater covers a portion of the substrate that extends from a center point of the substrate to an end point of the substrate.

In an example, the ramp heater has a length corresponding to a radius of the substrate. In an example, the ramp heater comprises one or more heat lamps. In an example, the gas is argon gas or nitrogen gas.

In an example, the system further comprises one or more evacuation ports for evacuation of the load lock chamber. In an example, the load lock chamber is evacuated using the one or more evacuation ports after the degas module degasses the substrate.

In another example, a system may comprise an equipment front end module (EFEM) comprising an aligner and configured to be coupled to a load lock chamber, and a degas module disposed within the EFEM and configured to degas the substrate, comprising a substrate holder configured to hold the substrate, wherein the substrate holder is mounted on the aligner, a rotation mechanism configured to rotate the substrate holder, a ramp heater configured to apply heat to the substrate, and a gas nozzle configured to blow gas toward the substrate.

In an example, the system further comprises one or more evacuation ports for evacuation of the EFEM. In an example, the EFEM is evacuated using the one or more evacuation ports after the degas module degases the substrate.

In an example, a degas module for degassing a substrate is provided. The degas module comprises a substrate holder configured to hold the substrate, a rotation mechanism configured to rotate the substrate holder, a ramp heater configured to apply heat to the substrate, and a gas nozzle configured to blow gas toward the substrate.

In an example, a method of degassing a substrate is provided, which comprises a degas module comprising a substrate holder, a rotation mechanism, a ramp heater, and a gas nozzle, the method comprising holding the substrate using the substrate holder, rotating the substrate holder using the rotation mechanism, applying heat to the substrate using the ramp heater, and blowing gas out of the gas nozzle toward the substrate.

For purposes of summarizing the invention and the advantages achieved over the prior art, certain objects and advantages of the invention have been described herein above. Of course, it is to be understood that not necessarily all such objects or advantages may be achieved in accordance with any particular aspect of the invention. Thus, for example, those skilled in the art will recognize that the invention may be embodied or carried out in a manner that achieves or optimizes one advantage or group of advantages as taught or suggested herein without necessarily achieving other objects or advantages as may be taught or suggested herein.

All of these aspects are intended to be within the scope of the invention herein disclosed. These and other aspects will become readily apparent to those skilled in the art from the following detailed description of certain aspects having reference to the attached figures, the invention not being limited to any particular aspects(s) disclosed.

### BRIEF DESCRIPTION OF THE DRAWINGS

A more complete understanding of exemplary aspects of the present disclosure can be derived by referring to the detailed description and claims when considered in connection with the following illustrative figures. These and other features, aspects, and advantages of the invention disclosed herein are described below with reference to the drawings of certain aspects, which are intended to illustrate and not to limit the invention. The illustrations presented herein are not meant to be actual views of any particular material, structure, or device, but are merely idealized representations that are used to describe aspects of the disclosure. For clarity and brevity, consistent reference numerals may be used throughout the figures for corresponding, similar, and/or identical elements.

To easily identify the discussion of any particular element or act, the most significant digit or digits in a reference number refer to the figure number in which that element is first introduced.

FIG. 1 illustrates an example system for degassing a substrate in accordance with one or more aspects of the disclosure.

FIG. 2 is a cross-sectional view of a degas module in accordance with one or more aspects of the disclosure.

FIG. 3 is a top-view of a degas module in accordance with one or more aspects of the disclosure.

It will be appreciated that elements in the figures are illustrated for simplicity and clarity and have not necessarily been drawn to scale. For example, the dimensions of some of the elements in the figures may be exaggerated relative to other elements to help improve understanding of illustrated aspects of the present disclosure.

### DETAILED DECRIPTION

Reference will now be made to the drawings wherein like reference numerals identify similar structural features or aspects of the subject disclosure. Further, in this disclosure, any two numbers of a variable can constitute a workable range of the variable, and any ranges indicated may include or exclude the endpoints. Additionally, any values of variables indicated (regardless of whether they are indicated with “about” or not) may refer to precise values or approximate values and include equivalents, and may refer to average, median, representative, majority, or other derived representative value. Further, in this disclosure, the terms “include,” “including,” “constituted by” and “having” can refer independently to “typically or broadly comprising,” “comprising,” “consisting essentially of,” or “consisting of” in some embodiments. In this disclosure, any defined meanings do not necessarily exclude ordinary and customary meanings in some aspects.

Although certain aspects and examples are disclosed below, it will be understood by those in the art that the invention extends beyond the specifically disclosed aspects and/or uses of the invention and obvious modifications and equivalents thereof. Thus, it is intended that the scope of the invention disclosed should not be limited by the particular disclosed aspects described below.

The particular implementations shown and described are illustrative of the invention and its best mode and are not intended to otherwise limit the scope of the aspects and implementations in any way. Indeed, for the sake of brevity, conventional manufacturing, connection, preparation, and other functional aspects of the system may not be described in detail or omitted entirely. Furthermore, the connecting lines shown in the various figures are intended to represent example functional relationships and/or physical couplings between the various elements. Many alternative or additional functional relationship or physical connections may be present in the practical system, and/or may be absent in some examples.

It is to be understood that the configurations and/or approaches described herein are examples in nature, and that these specific aspects or examples are not to be considered in a limiting sense, because numerous variations are possible. The specific routines or methods described herein may represent one or more of any number of processing strategies. Thus, the various acts illustrated may be performed in the sequence illustrated, in other sequences, or omitted in some cases.

The subject matter of the present disclosure includes all novel and nonobvious combinations and sub-combinations of the various processes, systems, and configurations, and other features, functions, acts, and/or properties disclosed herein, as well as any and all equivalents thereof.

Throughout this specification, a “chamber” may refer to an enclosed space suitable or configured for containing and/or processing one or more substrates. Additionally or alternatively, a chamber may refer to an enclosed space suitable or configured for containing and/or processing one or more substrates under controlled conditions. Additionally or alternatively, a chamber may refer to an enclosed space suitable or configured for isolation from the external environment to maintain specific environmental conditions, such as pressure, temperature, and/or gas composition. In some aspects, a chamber may refer to an interior cavity defined by outer walls and/or by one or more doors or ports for allowing substrates to enter and/or exit said cavity.

In this disclosure, a “load lock chamber” may refer to a chamber suitable or configured for transferring substrates between different environments, for example, between a high-vacuum environment and an atmospheric or low-vacuum environment. Additionally or alternatively, a load lock chamber may refer to a chamber suitable or configured for loading and/or unloading substrates into and/or out of a processing chamber. Additionally or alternatively, a load lock chamber may refer to a chamber suitable or configured to account for pressure differences between different environments during the transfer of substrates. Additionally or alternatively, a load lock chamber may refer to a chamber suitable or configured for isolating its interior from the external environment to maintain specific environmental conditions, such as pressure, temperature, and/or gas composition, during the transfer of substrates. Additionally or alternatively, a degas module may be disposed with a load lock chamber, which may be used to degas a substrate, as discussed in more detail herein.

In this specification, a “load lock chamber body” may refer to a structure forming the outer walls of a load lock chamber. Additionally or alternatively, a load lock chamber body may refer to a structure that provides mechanical support and/or fluid isolation for a load lock chamber. In some aspects, a load lock chamber body may comprise one or more materials suitable for maintaining the structural integrity and/or environmental isolation of a load lock chamber. Such materials may include, but are not limited to, metals, such as stainless steel or aluminum, and quartz. In some aspects, a load lock chamber body may include one or more ports or openings for the installation of pumps, valves, sensors, and/or other components necessary or beneficial for the operation of the load lock chamber. In some aspects, a load lock chamber body may be designed to withstand various environmental conditions, such as vacuum, elevated temperatures, and/or exposure to reactive gases. In some aspects, a load lock chamber body may be integrated with one or more structural supports, such as frames or brackets, to provide additional mechanical stability.

Throughput this disclosure, “vacuum” may refer to an environment with significantly reduced pressure compared to atmospheric pressure. Additionally or alternatively, vacuum may refer to an environment exhibiting low-vacuum conditions (e.g., less than or equal to 100 kPa and greater than 100 Pa), medium-vacuum conditions (e.g., less than or equal to 100 Pa and greater than 0.1 Pa), high-vacuum conditions (e.g., less than or equal to 0.1 kPa and greater than 1 μPa), ultra-high-vacuum conditions (e.g., less than or equal to 1 μPa and greater than 1 nPa), or extreme-high-vacuum conditions (e.g., less than or equal to 1 nPa).

In this specification, the term “module” may refer to a self-contained unit or component that performs a specific function within a larger system. Additionally or alternatively, a module may refer to a subsystem that can be integrated with other subsystems to form a complete system. Further, a “degas module” may refer to a module suitable or configured for degassing a substrate. Further, a “transfer module” may refer to a module suitable or configured for transferring substrates between separate locations in a substrate processing environment. Additionally or alternatively, a transfer module may refer to a module suitable or configured to maintain a controlled environment to prevent contamination of substrates during transfer. In some aspects, a transfer module may comprise fluid circulation means and/or filtering means to ensure the cleanliness of the environment inside the transfer module. In some aspects, a transfer module may comprise one or more fluid circulation systems suitable or configured to circulate clean air or other gases within the transfer module to prevent substrate contamination. In some aspects, a transfer module may comprise one or more filtering systems suitable or configured to remove particles, contaminants, and/or other impurities from the environment inside the transfer module. In some aspects, a transfer module may comprise one or more robotic arms or other mechanical means suitable or configured for moving substrates between different locations within the transfer module. In some aspects, a transfer module may be implemented as an Equipment Front End Module (EFEM).

Throughout this specification, a “vacuum chamber” may refer to a chamber suitable or configured for containing, transferring, and/or processing one or more substrates under vacuum. Additionally or alternatively, a “vacuum chamber” may refer to a chamber suitable or configured for performing one or more processes that require a vacuum environment, such as deposition, etching, and/or other semiconductor manufacturing processes. In some aspects, a vacuum chamber may be implemented as a wafer transfer chamber. In some aspects, a vacuum chamber may comprise a substrate transfer robot to enable substrate transfer between different aspects, such as a load lock arrangement and one or more substrate processing chambers. In some aspects, a vacuum chamber may be fluidically coupled to one or more pumps for evacuating the vacuum chamber to achieve and maintain a vacuum environment. In some aspects, a vacuum chamber may comprise one or more valves suitable or configured to control the flow of gases into and/or out of the vacuum chamber. In some aspects, a vacuum chamber may comprise one or more sensors, such as one or more pressure sensors and/or one or more temperature sensors, to monitor and control the environmental conditions within the vacuum chamber.

In this disclosure, a “substrate” may refer to any underlying material or materials that may be used to form, or upon which, a device, a circuit, or a film may be formed. Additionally or alternatively, a substrate may refer to any material that provides a foundation for the fabrication of microelectronic, optoelectronic, or photonic devices. Additionally or alternatively, a substrate may refer to an object including a bulk material, such as silicon (e.g., single-crystal silicon), other Group IV materials, such as germanium, or compound semiconductor materials, such as GaAs, and optionally one or more layers overlying or underlying the bulk material and/or various structures, such as recesses, vias, lines, and the like formed within or on at least a portion of a layer of the substrate. In some aspects, a substrate may comprise a semiconductor wafer. In some aspects, a substrate may comprise a layered structure, including but not limited to, silicon-on-insulator (SOI) structure, wherein a thin layer of silicon is separated from a bulk silicon layer by an insulating layer, and epitaxial structures, wherein one or more epitaxial layers are grown on a bulk material layer.

Throughout this specification, a “substrate holder” may refer to a device or structure suitable or configured for holding one or more substrates in a load lock chamber. Additionally or alternatively, a substrate holder may refer to a device or structure suitable or configured for holding one or more substrates in a specific arrangement in a load lock chamber, for example, to facilitate substrate transfer and/or processing, and/or degassing a substrate. In some aspects, a substrate holder may be configured to rotate a substrate with a rotation mechanism. In some aspects, a substrate holder may be configured to hold a single substrate, whereas in other aspects, a substrate holder may be configured to hold a plurality of substrates, e.g., two substrates, three substrates, four substrates, five substrates, and so forth. In other aspects, a substrate holder may be configured to hold a plurality of substrates in a stacked arrangement at a plurality of substrate positions. In some aspects, a substrate holder may be configured to hold substrates in a vertically stacked arrangement, wherein individual substrates extend laterally and face vertical directions in the operation position of a load lock arrangement; a laterally stacked arrangement, wherein individual substrates extend vertically and face lateral directions in the operation position of a load lock arrangement; or a slanted stacked arrangement, wherein individual substrates are arranged at an angle with respect to the vertical direction. In some aspects, a substrate holder may comprise one or more mechanical components, such as clamps, brackets, or shelves, to secure the substrates in place. In some aspects, a substrate holder may comprise one or more alignment features, such as grooves or notches, to ensure the precise positioning of the substrates. In some aspects, automated substrate transfer to and from a substrate holder may be accomplished using one or more robotic arms or other mechanical substrate transfer means.

In this disclosure, a “heater” may refer to a device or apparatus suitable or configured to generate heat or thermal energy. Further, a “ramp heater” may refer to a heater suitable or configured for generating and transmitting heat or thermal energy, using, for example, one or more heat lamps. In an example, a heat lamp may be any lamp used for the semiconductor fabrication process. In an example, the lamp is a heat lamp that provides radiant energy or heat inside of a chamber.

In this specification, a “chemical vapor deposition chamber” or “CVD chamber” may refer to a chamber, wherein one or more gaseous compounds decompose to deposit a layer onto a substrate. Further, a “cyclic chemical vapor deposition chamber” or “cyclic CVD chamber” may refer to a CVD chamber sequentially and/or cyclically providing precursors, and/or reactants, and/or active species to deposit a layer onto said substrate.

Throughout this specification, an “atomic layer deposition chamber” or “ALD chamber” may refer to a cyclic CVD chamber configured for purging between provision of precursors, and/or reactants, and/or active species. Typically, purging may be accomplished by flushing said ALD chamber or a process station thereof with an inert gas. Additionally or alternatively, an atomic layer deposition chamber may refer to a cyclic CVD chamber suitable for or configured to deposit a conformal layer, e.g., a layer with a step coverage (SC) of at least 95%, or 99%, or about 100% for a feature with an aspect ratio (AR) of 3:1, or 5:1, or 10:1, onto a substrate.

In some aspects, the presently described methods, devices, and apparatuses may be useful in the fields of microfabrication and nanofabrication. In some aspects, the presently described methods, devices, and apparatuses may be useful in the fields of microelectromechanical systems, microsystems, photonics, photovoltaics, display devices, and/or semiconductor manufacturing technology. In some aspects, the presently described methods, devices, and apparatuses may be beneficial for handling and/or treatment of substrates, e.g., semiconductor wafers or solid-state devices, during their fabrication. In some aspects, they may be applied to substrate processing apparatuses comprising a plurality of work-stations. In some aspects, they may contribute to sustainable manufacturing practices in semiconductor production. In some aspects, the presently described methods, devices, and apparatuses may be useful for increasing the throughput, and/or reducing the electricity consumption, and/or reducing the process gas consumption of modular substrate processing apparatuses and/or increasing the quality of films fabricated using substrate processing apparatuses.

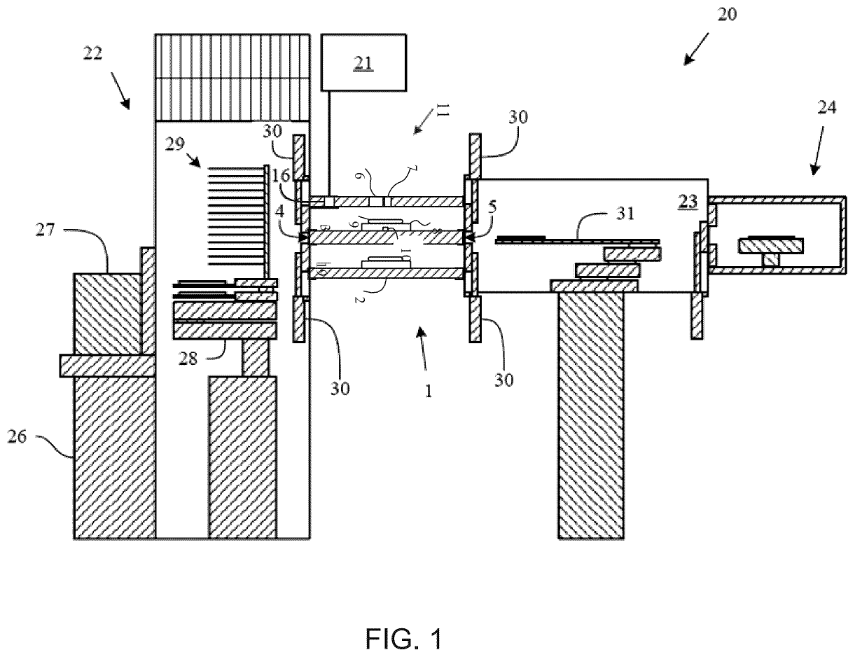

FIG. 1 schematically illustrates a substrate processing apparatus 20 provided with a degas module 11 disposed within a load lock arrangement 1 according to one or more aspects described herein. Other aspects may or may not be identical or similar to the description with reference to FIG. 1.

The load lock arrangement 1 of FIG. 1 comprises a load lock chamber body 2 that defines a load lock chamber 3. The substrate processing apparatus 20 of FIG. 1 comprises a transfer module 22 and a vacuum chamber 23, and the load lock chamber body 2 comprises a first face 4 configured for coupling to the transfer module 22 and a second face 5 configured for coupling to the vacuum chamber 23.

Even if not explicitly shown in FIG. 1, a substrate processing apparatus may generally comprise any suitable number of load lock arrangements according to the first aspect, for example, one or more load lock arrangements, two or more load lock arrangements, three or more load lock arrangements, and so forth. Any or all of such load lock arrangement may comprise any suitable number of ramp heaters, and any two individual ramp heaters of a load lock arrangement may be associated with separate load lock chambers or the same load lock chamber.

The load lock arrangement 1 further comprises a degas module 11 that comprises a ramp heater 6 configured to apply heat to a substrate 9, a substrate holder 8 configured to hold the substrate 9, a gas nozzle 7 configured to blow gas toward the substrate 9, and a rotation mechanism 10 configured to rotate the substrate holder 8. In this manner, the degas module 11 may degas a substrate (e.g., desorb absorbed moisture and/or gas from a substrate). In some aspects, such a load lock arrangement with a degas module may increase the throughput, and/or reduce the electricity consumption, and/or reduce the process gas consumption of a substrate processing apparatus.

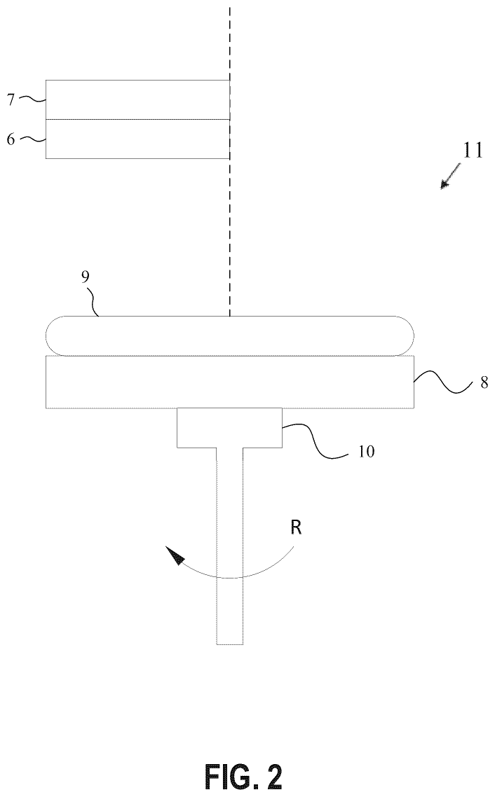

In an example, the ramp heater 6 and the gas nozzle 7 are arranged above the load lock chamber 3, and the ramp heater 6 is above a portion of the substrate 9 (shown in more detail at FIG. 2) and configured to apply heat toward the substrate 9. In this manner, the ramp heater 6 may be configured to apply heat to the substrate 9, in order to heat the surface of the substrate 9, and thereby remove moisture, gas, and/or contaminants from the surface of the substrate 9. Further, the gas nozzle 7 blows an inert gas, such as argon or nitrogen, toward the heated substrate 9, causing the moisture and/or gas on the surface of the substrate 9 to be blown away from the substrate 9.

In an example, the substrate holder 8 is coupled to a rotation mechanism 10 (shown in more detail at FIG. 2), which causes the substrate holder 8 (and by extension the substrate 9) to be rotated while the ramp heater 6 applies heat to the substrate 9 in a uniform manner. Further, the gas nozzle 7 blows gas toward the heated substrate 9 while the rotation mechanism 10 rotates the substrate 9. In an example, the ramp heater 6 may be configured to generate thermal radiation (e.g., heat). In other aspects, a ramp heater may be configured to generate thermal radiation at any suitable output power(s). For example, in some aspects a ramp heater may be configured to generate thermal radiation at an output power greater than or equal to 25 W, or to 50 W, or to 100 W, or to 200 W, or to 300 W. An example of a typical power output for the ramp heater 6 is about 300 W. Compared to using a larger ramp heater, such as one that could require as much at 100× power output (e.g., greater than 30000 W), a smaller ramp heater may use less output power, resulting in significantly increased energy efficiency, while maintaining a high throughput. This benefit may be realized in part due to the rotation of the substrate 9, because the size of the ramp heater 6 may only need to cover a portion of the substrate 9, rather than the entire substrate 9.

In FIG. 1, the load lock chamber body 2 comprises one or more evacuation ports 16 for evacuation of the load lock chamber 3. In some aspects, wherein a load lock arrangement comprises a degas module for degassing moisture from a substrate arranged in a load lock chamber defined by the load lock chamber body, the load lock chamber body further comprises one or more evacuation ports for evacuation of the load lock chamber, which may enable simultaneous removal of moisture and/or gas from a substrate and evacuating the load lock chamber, which may, in turn, increase a throughput of a substrate processing apparatus provided with such a load lock arrangement. In other aspects, a load lock chamber body may or may not comprise one or more evacuation ports for evacuation of a load lock chamber. For example, in some aspects, a transfer module and/or a vacuum chamber may be configured for pressurization and/or evacuation to facilitate substrate transport using a load lock arrangement. In an example, after gas and/or moisture are removed from the substrate 9, the one or more evacuation ports 16 may be used to suck out the gas and/or moisture that was removed from the substrate 9 using the processes described above.

In FIG. 1, the load lock chamber body 2 further defines a second load lock chamber 19 for substrate transfer between the transfer module 22 and the vacuum chamber 23. The substrate processing apparatus 20 is configured to utilize the load lock chamber 3 for substrate transfer from the transfer module 22 to the vacuum chamber 23 and to utilize the second load lock chamber 19 for substrate transfer from the vacuum chamber 23 to the transfer module 22. In other aspects, a load lock chamber body may define any suitable number of load lock chambers, for example, one or more load lock chambers, two or more load lock chambers, three or more load lock chambers, and so forth. In some aspects, wherein a load lock arrangement comprises a ramp heater for desorbing adsorbed moisture (e.g., degassing) a substrate held in a load lock chamber, a load lock chamber body may define the load lock chamber, a second load lock chamber arranged below the load lock chamber in an operation position of a load lock arrangement, a third load lock chamber arranged laterally adjacent to the load lock chamber in the operation position, and a fourth load lock chamber arranged laterally adjacent to the second load lock chamber and below the third load lock chamber in the operation position. In some such aspects, the load lock chamber, the second load lock chamber, the third load lock chamber, and the fourth load lock chamber may be arranged in a rectangular arrangement, when viewed from opposite a first face and/or from opposite a second face. Further, in some such aspects, the load lock arrangement may comprise a second ramp heater for degassing and/or desorbing adsorbed moisture from substrate(s) held in the third load lock chamber.

The load lock arrangement 1 of FIG. 1 is configured to accommodate at most one substrate in the load lock chamber 3. In FIG. 1, the substrate 9 to be held by the substrate holder 8 consists of the at most one substrate, and the load lock arrangement 1 is provided with the substrate holder 8 in the absence of other substrate holding means for holding further substrates in the load lock chamber 3. In some aspects, a load lock arrangement being configured to accommodate at most two substrates in two respective load lock chambers (e.g., load lock chamber 3 and second load lock chamber 19) may enable desorbing adsorbed moisture (e.g., degassing) from the at most one substrate more rapidly and/or more uniformly, which may, in turn, increase a throughput of a substrate processing apparatus provided with such a load lock arrangement. In other aspects, a load lock arrangement may or may not be configured to accommodate at most two substrates in a load lock chamber.

In an aspect of FIG. 1, the substrate processing apparatus 20 comprises one or more load ports 26 configured for coupling to one or more substrate carriers 27, such as Front Opening Unified Pods (FOUPs) or the like. The one or more load ports 26 are coupled to the transfer module 22 for substrate transfer between the one or more substrate carriers 27 and the transfer module 22. In other aspects, a substrate processing apparatus may or may not comprise such one or more load ports.

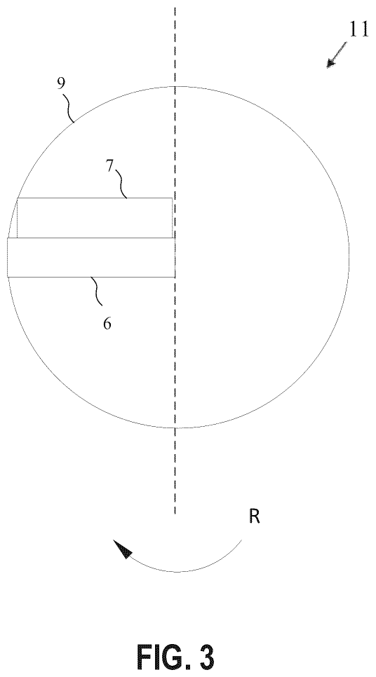

The transfer module 22 of FIG. 1 may be implemented as an Equipment Front End Module (EFEM). The transfer module 22 is configured to maintain a clean environment inside the transfer module 22 to avoid substrate contamination during substrate transfer via the transfer module 22. Although not depicted in FIG. 1, the transfer module 22 may comprise fluid circulation means and/or filtering means to ensure the cleanliness of the environment inside the transfer module 22. In other aspects, a transfer module may be implemented in any suitable manner. Although not depicted in FIG. 1, a degas module may be disposed within the transfer module 22 and perform similar degassing functions. As an example, in the case in which a degas module is disposed within the transfer module 22 (e.., within the EFEM), the degas module may perform similar functions as shown and described with reference to FIG. 2 and FIG. 3. Further, when the degas module is disposed within the EFEM, the substrate 9 and/or substrate holder 8 would be mounted on, for example, an EFEM aligner, and the EFEM aligner would be configured to rotate the substrate 9 and/or the substrate holder 8 by using the rotation mechanism 10. In some cases, one or more aligners may similarly be used to degas one or more substrates using one or more degas modules.

The transfer module 22 of FIG. 1 comprises one or more substrate cooling stages 29 to facilitate substrate cooling after substrate processing and a front-end substrate transfer robot 28 to enable substrate transfer between at least any of the one or more load ports 26, the one or more substrate cooling stages 29, and the load lock arrangement 1. In other aspects, a transfer module may or may not comprise one or more substrate cooling stages. In such other aspects, a transfer module may comprise any suitable substrate transfer means, for example, one or more front-end substrate transfer robots or the like to enable substrate transfer between any suitable substrate positions, for example, between at least any of one or more load ports, one or more substrate cooling stages and a load lock arrangement.

In an example, the load lock arrangement 1 comprises a plurality of gate valves 30 for providing fluid-tight sealing between the load lock chamber 3 and each of the transfer module 22 and the vacuum chamber 23 as well as between the second load lock chamber 19 and each of the transfer module 22 and the vacuum chamber 23. In other aspects, a load lock arrangement may or may not comprise one or more gate valves suitable for and/or configured for providing fluid-tight sealing between a load lock chamber and one or more of a transfer module and a vacuum chamber and/or between a second load lock chamber and one or more of a transfer module and a vacuum chamber. In other aspects, a load lock arrangement may or may not comprise any suitable number of gate valves for providing fluid-tight sealing for any one or more load lock chambers defined by a load lock chamber body.

In FIG. 1, the substrate processing apparatus 20 comprises a vacuum pump 21 fluidically coupled to the load lock chamber 3 for evacuation of the load lock chamber 3. The vacuum pump 21 of FIG. 1 is coupled to the one or more evacuation ports 16 and configured to evacuate the load lock chamber 3 after the degas module 11 degasses the substrate 9. In some aspects, a substrate processing apparatus comprising a vacuum pump fluidically coupled to a load lock chamber for evacuation of the load lock chamber may facilitate simultaneously desorbing adsorbed moisture (e.g., degassing) from one or more substrates and evacuating the load lock chamber, which may, in turn, increase a throughput of a substrate processing apparatus provided with such a vacuum pump. In other aspects, a substrate processing apparatus may or may not comprise a vacuum pump fluidically coupled to the load lock chamber for evacuation of the load lock chamber. In some aspects, wherein a substrate processing apparatus comprises such a vacuum pump, the vacuum pump may be fluidically coupled to any suitable number of further chambers and/or modules for evacuation thereof.

In some aspects, a substrate processing apparatus may be configured to affect evacuation the load lock chamber while a degas module degasses a substrate. In some aspects, a load lock chamber of a substrate processing apparatus may be fluidically coupled to an external evacuation source separate from the substrate processing apparatus for evacuation of a load lock chamber. In some such aspects, the substrate processing apparatus may be configured to evacuate a load lock chamber using an external evacuation source while a degas module degasses one or more substrates. In other aspects, wherein a substrate processing apparatus comprises a vacuum pump fluidically coupled to a load lock chamber for evacuation of thereof, the vacuum pump may or may not be coupled to one or more evacuation ports, and/or the vacuum pump may or may not be configured to evacuate a load lock chamber while a degas module degasses one or more substrates.

In FIG. 1, the substrate processing apparatus 20 comprises one or more deposition chambers 24 coupled to the vacuum chamber 23. Although a single deposition chamber of the one or more deposition chambers 24 is depicted in FIG. 1, the substrate processing apparatus 20 of the embodiment of FIG. 1 may comprise any suitable number, e.g., one or more, two or more, three or more, and so forth, of deposition chambers coupled to the vacuum chamber 23. In some aspects, a load lock arrangement comprising a degas module for degassing one or more substrates may improve the quality and/or adhesion properties of films, e.g., electrically conductive and/or metallic films, deposited by one or more deposition chambers of a substrate processing apparatus. Further, even if not depicted in FIG. 1, a substrate processing apparatus may comprise any suitable number of one or more other types of substrate processing chambers, such as pre-cleaning chambers, pre-treatment chambers, etching chambers, post-treatment chambers, and the like, in addition to or as an alternative to one or more deposition chambers. Although not depicted in FIG. 1, a degas module may be disposed within a deposition chamber and perform similar degassing functions.

At least part of the one or more deposition chambers 24 of FIG. 1 may be implemented as chemical vapor deposition chambers, such as cyclic chemical vapor deposition chamber, e.g., atomic layer deposition chambers. In other aspects, wherein a substrate processing apparatus comprises one or more deposition chambers coupled to a vacuum chamber, any deposition chamber of the one or more deposition chambers may be implemented in any suitable manner(s), for example, as chemical vapor deposition chambers, e.g., atomic layer deposition chambers; physical vapor deposition chambers, e.g., sputtering chambers and/or electron beam evaporation chambers; spin coating chambers; and/or spray pyrolysis chambers.

In FIG. 1, the vacuum chamber 23 may be implemented as a wafer transfer chamber. The vacuum chamber 23 comprises a back-end substrate transfer robot 31 to enable substrate transfer between at least any of the load lock arrangement 1 and the one or more deposition chambers 24. In other aspects, a vacuum chamber may or may not comprise any suitable substrate transfer means, for example, one or more back-end substrate transfer robots or the like. In some aspects, wherein a substrate processing apparatus comprises a vacuum chamber coupled to a load lock arrangement, the vacuum chamber may be implemented as a substrate processing chamber, such as a deposition chamber, an etching chamber, or the like.

FIG. 2 schematically illustrates a degas module 11 in accordance with one or more aspects described herein. Even if not depicted in FIG. 2, the degas module 11 of FIG. 2 may comprise any features of load lock arrangements disclosed within this specification. In some cases, when the degas module 11 is located within an EFEM (and mounted on an EFEM aligner), the degas module 11 may perform similar functions as described herein. Other aspects may or may not be identical or similar to the aspects of FIG. 2. The degas module 11 of FIG. 2 comprises a ramp heater 6 configured to apply heat to a substrate 9, a substrate holder 8 configured to hold the substrate 9, a gas nozzle 7 configured to blow gas toward the substrate 9, and a rotation mechanism 10 configured to rotate the substrate holder 8. Although the ramp heater 6 and the gas nozzle 7 of FIG. 2 are depicted as being on top of each other, this is for illustrative purposes. The ramp heater 6 and the gas nozzle 7 would, as an example, be located next to each other (similar to what is shown by FIG. 3), such that the ramp heater 6 and the gas nozzle 7 would be both located in the same direction as the rotation R.

In an example, the ramp heater 6 may be configured to apply heat to the substrate 9, in order to heat a surface of the substrate 9, and thereby remove moisture, gas, and/or contaminants from the surface of the substrate 9. Further, the gas nozzle 7 blows an inert gas, such as argon or nitrogen, toward the heated substrate 9, causing the moisture and/or gas on the surface of the substrate 9 to be blown away from the substrate 9. In an example, the gas nozzle 7 may include an array of one or more gas nozzles without departing from the scope of the disclosure.

In an example, the substrate holder 8 is coupled to a rotation mechanism 10, which causes the substrate holder 8 (and similarly the substrate 9) to be rotated while the ramp heater 6 applies heat to the substrate 9 in a uniform manner. Further, the gas nozzle 7 blows gas toward the heated substrate 9 while the rotation mechanism 10 rotates the substrate 9. In this manner, the degas module 11 may degas a substrate (e.g., desorb absorbed moisture and/or gas from a substrate).

Also or alternatively, the substrate holder 8 is further configured to be mechanically coupled to the rotation mechanism 10, and the rotation mechanism 10 is configured to rotate the substrate holder 8 (and thus the substrate 9) about a central axis of the substrate. Although FIG. 2 shows a rotation R in a clockwise direction, any circular motion in a direction that rotates the substrate holder 8 may be used without departing from the scope of the disclosure. In some cases, when the degas module 11 is disposed within the transfer chamber 22 (e.g., within the EFEM and mounted on an EFEM aligner), the aligner may similarly the rotation mechanism 10 as described herein. Alternatively, the aligner may similarly rotate the substrate holder 8 and/or substrate 9.

In an example, the ramp heater 6 has a length that corresponds to a radius of the substrate 9. When the substrate 9 is rotated in an R direction about a central axis of the substrate 9, heat from the ramp heater 6 may be applied uniformly across the substrate 9. The rotational speed of the rotation mechanism 10 may be any suitable speed, such that the heat applied by the ramp heater 6 can uniformly heat the entire surface of the substrate 9.

In an example, a method of degassing a substrate 9 is provided, which comprises a degas module 11 comprising a substrate holder 8, a rotation mechanism 10, a ramp heater 6, and a gas nozzle 7, the method comprising holding the substrate 9 using the substrate holder 8, rotating the substrate holder 8 using the rotation mechanism 10, applying heat to the substrate 9 using the ramp heater 6, and blowing gas out of the gas nozzle 7 toward the substrate 8.

The load lock arrangement 1 of FIG. 2 is configured to accommodate at most one substrate in the load lock chamber 3. In FIG. 1, the substrate 9 to be held by the substrate holder 8 may include the at most one substrate, and the load lock arrangement 1 is provided with the substrate holder 8 in the absence of other substrate holding means for holding further substrates in the load lock chamber 3. In some aspects, a load lock arrangement being configured to accommodate at most two substrates in two respective load lock chambers (e.g., load lock chamber 3 and second load lock chamber 19) may enable desorbing adsorbed moisture from the at most two substrates more rapidly and/or more uniformly, which may, in turn, increase a throughput of a substrate processing apparatus provided with such a load lock arrangement. In other aspects, a load lock arrangement may or may not be configured to accommodate at most two substrates in a load lock chamber.

FIG. 3 is a top-view of a degas module 11, which comprises a ramp heater 6 configured to apply heat to one or more substrates 9, a substrate holder 8 (not shown) configured to hold the substrate 9, a gas nozzle 7 configured to blow gas toward the substrate 9, and a rotation mechanism 10 configured to rotate the substrate holder 8.

In FIG. 3, the entire surface of the substrate 9 can be heated as the rotation mechanism 10 (not shown) rotates the substrate 9, in the example in which the length of the ramp heater 6 corresponds to a radius of the substrate 9. In this manner, the heat applied by the ramp heater 6 can uniformly heat the entire surface of the substrate 9 while the substrate 9 is rotated about its central axis.

Gaz nozzle 7 blows gas at the substrate 9 while heat is applied, so that after the moisture and/or gas from the substrate 9 is removed from the surface of the substrate 9, gas blown from the gas nozzle 7 and toward the substrate 9 may remove the moisture and/or gas from the substrate, thereby degassing the substrate 9. Inert gas, such as argon, nitrogen or the like, may be used without departing from the scope of the disclosure. As an example, due to the ramp heater 6 and the gas nozzle 7 being located next to each other in the manner depicted by FIG. 3, the temperature of the surface of the substrate 9 may be higher when the gas nozzle 7 blows gas toward the substrate 9. This may lead to the benefit of moisture being more easily desorbed from the substrate 9 due to the increased molecular motion/energy.

In an example, the ramp heater 6 has a length that corresponds to a radius of the substrate 9. When the substrate 9 is rotated in an R direction about a central axis of the substrate 9, heat from the ramp heater 6 may be applied uniformly across the substrate 9.

The example aspects of the disclosure described above do not limit the scope of the invention, since these aspects are merely examples, which is defined by the appended claims and their legal equivalents. Any equivalent aspects are intended to be within the scope of this invention. Indeed, various modifications of the disclosure, in addition to those shown and described herein, such as alternative useful combinations of the elements described, may become apparent to those skilled in the art from the description. Such modifications and aspects are also intended to fall within the scope of the appended claims.

Although but a few example systems and methods for degassing a substrate have been disclosed in detail above, those skilled in the art will readily appreciate that many modifications are possible in the example aspects without materially departing from the intent and purpose of the example systems and method as disclosed herein. Accordingly, all such modifications of systems and methods for degassing a substrate are intended to be included within the scope of this disclosure as defined in the following claims.

What is claimed is:

1. A system for degassing a substrate comprising:
an equipment front end module (EFEM) comprising an aligner and configured to be coupled to a load lock chamber; and
a degas module disposed within the EFEM and configured to degas the substrate, comprising:
a substrate holder configured to hold the substrate, wherein the substrate holder is mounted on the aligner;
a rotation mechanism configured to rotate the substrate holder;
a ramp heater configured to apply heat to the substrate; and
a gas nozzle configured to blow gas toward the substrate.

2. The system of claim 1, wherein the rotation mechanism rotates the substrate holder about a central axis of the substrate.

3. The system of claim 1, wherein the ramp heater covers a portion of the substrate that extends from a center point of the substrate to an end point of the substrate.

4. The system of claim 1, wherein the ramp heater has a length corresponding to a radius of the substrate.

5. The system of claim 1, wherein the ramp heater comprises one or more heat lamps.

6. The system of claim 1, wherein the gas is argon gas or nitrogen gas.

7. The system of claim 1, further comprising one or more evacuation ports for evacuation of the EFEM.

8. The system of claim 7, wherein the EFEM is evacuated using the one or more evacuation ports after the degas module degasses the substrate.

9. A degas module for degassing a substrate comprising:
a substrate holder configured to hold the substrate;
a rotation mechanism configured to rotate the substrate holder;
a ramp heater configured to apply heat to the substrate; and
a gas nozzle configured to blow gas toward the substrate.

10. The degas module of claim 9, wherein the rotation mechanism rotates the substrate holder about a central axis of the substrate.

11. The degas module of claim 9, wherein the ramp heater covers a portion of the substrate that extends from a center point of the substrate to an end point of the substrate.

12. The degas module of claim 9, wherein the ramp heater has a length corresponding to a radius of the substrate.

13. The degas module of claim 9, wherein the ramp heater comprises one or more heat lamps.

14. The degas module of claim 9, wherein the gas is argon gas or nitrogen gas.

15. A method of degassing a substrate, comprising a degas module comprising a substrate holder, a rotation mechanism, a ramp heater, and a gas nozzle, the method comprising:
holding the substrate using the substrate holder;
rotating the substrate holder using the rotation mechanism;
applying heat to the substrate using the ramp heater; and
blowing gas out of the gas nozzle toward the substrate.

16. The method of claim 15, wherein the rotation mechanism rotates the substrate holder about a central axis of the substrate.

17. The method of claim 15, wherein the ramp heater covers a portion of the substrate that extends from a center point of the substrate to an end point of the substrate.

18. The method of claim 15, wherein the ramp heater has a length corresponding to a radius of the substrate.

19. The method of claim 15, wherein the ramp heater comprises one or more heat lamps.

20. The method of claim 15, wherein the gas is argon gas or nitrogen gas.

21. A system for degassing a substrate comprising:
a load lock chamber body, defining a load lock chamber and comprising a first face configured to be coupled to a transfer module and a second face configured to be coupled to a vacuum chamber; and
a degas module disposed within the load lock chamber and configured to degas the substrate, comprising:
a substrate holder configured to hold the substrate;
a rotation mechanism configured to rotate the substrate holder;
a ramp heater configured to apply heat to the substrate; and
a gas nozzle configured to blow gas toward the substrate.

22. The system of claim 21, wherein the rotation mechanism rotates the substrate holder about a central axis of the substrate.

23. The system of claim 21, wherein the ramp heater covers a portion of the substrate that extends from a center point of the substrate to an end point of the substrate.

24. The system of claim 21, wherein the ramp heater has a length corresponding to a radius of the substrate.

25. The system of claim 21, wherein the ramp heater comprises one or more heat lamps.

26. The system of claim 21, wherein the gas is argon gas or nitrogen gas.

27. The system of claim 21, further comprising one or more evacuation ports for evacuation of the load lock chamber.

28. The system of claim 27, wherein the load lock chamber is evacuated using the one or more evacuation ports after the degas module degasses the substrate.
